(19) United States
(12) Patent Application Publication
(10) Pub. No.: US 2016/0111443 A1
(43) Pub. Date: Apr. 21, 2016

(54) GLASS PANEL AND METHOD FOR MANUFACTURING THE SAME

(71) Applicant: SHENZHEN CHINA STAR OPTOELECTRONICS TECHNOLOGY CO. LTD., Shenzhen, Guangdong (CN)

(72) Inventor: Shishuai HUAN, Shenzhen, Guangdong (CN)

(21) Appl. No.: 14/416,805

(22) PCT Filed: Dec. 16, 2014
(86) PCT No.: PCT/CN2014/093985

§ 371 Date: Jan. 23, 2015

(30) Foreign Application Priority Data
Oct. 20, 2014 (CN) 201410559637.4

(51) Int. Cl. H01L 27/12; G02F 1/1368

(52) U.S. Cl. CPC H01L 27/124; G02F 1/1368; H01L 27/1288

(57) ABSTRACT

The field of manufacturing liquid crystal display panels, and in particular a modified glass panel is related. The glass panel comprises: a first metal layer used for forming scan lines and charge sharing lines, and a wiring metal layer used for forming connecting wires, wherein the connecting wires each have a via hole portion, and connect to the scan line and/or the charge sharing line via a via hole in the via hole portion. A corresponding manufacturing method is further provided. In this manner, a subsequently activated scan line can be used for activating a charge sharing line in a previous group. Hence, a reduced amount of chips on film will be used in the manufacturing and packaging procedures.

### CROSS-REFERENCE TO RELATED APPLICATIONS

The present application claims benefit of Chinese patent application CN 201410559637.4, entitled “Glass panel and mask used in manufacturing the same” and filed on Oct. 20, 2014, the entirety of which is incorporated herein by reference.

### FIELD OF THE DISCLOSURE

The present disclosure relates to the field of manufacturing liquid crystal display panels, and in particular, to a glass panel and a method for manufacturing the glass panel.

### BACKGROUND OF THE DISCLOSURE

In the prior art, procedure steps as depicted in FIG. 1 are generally used for manufacturing an array substrate of a thin film transistor liquid crystal display. As indicated in FIG. 1, the procedure steps comprise: step a) coating a film on a glass substrate; step b) coating a photoresist material on the film; step c) illuminating the glass panel coated with the photoresist material through a mask 105; step d) developing images; step e) etching the glass panel; and step f) removing the photoresist material from the glass substrate that has been treated using a photoresist removal solution 106. A coating having a pattern can be subsequently obtained, which precedes circulation back to step a) for treatment of a next coating. Steps a) to f) are constantly repeated to obtain a desired glass panel having a plurality of coatings.

In the prior art, a five mask procedure is commonly employed for manufacturing a glass panel of an array substrate used in a liquid crystal display. In the five mask procedure, the steps as shown in FIG. 1 are substantially repeated for five times, in which five layers are formed on the glass substrate through five different masks 105.

FIG. 2 shows a cross-section view of a glass panel manufactured through the five mask procedure. As FIG. 2 illustrates, a glass substrate 1 is located at a lowermost layer. A gate 2, which is provided in a first metal layer M1, is formed on the glass substrate 1 through the steps as shown in FIG. 1. An insulation layer 3 is then covered on the gate 2. On the insulation layer 3, an active layer comprising, for example, different semiconductor materials 4 and 5, is formed through a second mask. After that, a source 6 and a drain 7, which are provided in a second metal layer M2, are formed on the active layer through a third mask. A via hole layer having a via hole 8 is then formed on the source 6 and the drain 7 through a fourth mask. On the via hole layer, an ITO layer 9 used as an electrode is formed through a fifth mask.

FIG. 3 shows a liquid crystal pixel unit in the prior art. In order to improve a viewing angle and reduce color shift, a low color shift design is generally adopted in a large size panel. For example, through adding domains in a pixel unit, one pixel unit can comprise four pixel domains. If one pixel unit is further divided into a main area 21 and a sub area 22, eight pixel domains can be obtained in one pixel unit, thereby achieving the purposes of improving the viewing angle and eliminating color shift.

The main area 21 and the sub area 22 of the pixel unit are generally energized through two or more different thin film transistors. FIG. 4 is an equivalent circuit diagram of a common pixel unit with a low color shift design. One pixel unit comprises a main area and a sub area. When a scan line 11 is activated, a thin film transistor Tₘₐᵢₙ located at the main area and a thin film transistor T_{sub} located at the sub area are activated, and respectively transmit electric signals of a data line 13 to liquid crystal capacitors and storage capacitors that are located at the main area and the sub area. When the scan line 11 is deactivated, and a charge sharing line 12 is activated, a sharing thin film transistor Tcs is activated, which partly releases voltages of a liquid crystal capacitor Clc_{sub} and a storage capacitor CST_{sub} that are located in the sub area into a sharing capacitor Cb. Thus, a voltage difference will occur between the sub area and the main area of the pixel unit, whereby the purpose of reducing color shift can be achieved with the aid of adjustment and control.

In a common design, the scan line 11 and the charge sharing line 12 are independent of each other, and therefore are necessary to be controlled through respective switches for the scan line 11 and the charge sharing line 12 during display, so as to achieve a low color shift design. Because of such independence between the scan line 11 and the charge sharing line 12, a relatively large consumption of chips on film (COF) are necessary in the manufacturing and packaging procedures.

In another low color shift design, a subsequently activated scan line 11 is used to activate a charge sharing line 12 in a previous group. For example, calculated from an end of the panel, when an n^{th} scan line corresponds to an n^{th} line of pixel units, an n^{th} charge sharing line 12 is activated via an (n+p)^{th} scan line 11, which is termed as an n+p type low color shift design. Through such design, the consumption of chips on film can be decreased. FIG. 5 shows a signal diagram and a circuit diagram of an n+2 type low color shift structure.

In the prior art, however, the n+1, n+2, and even n+p type low color shift designs each require a separate type of masks for performance of the procedure steps as depicted in FIG. 1. The manufacturing procedures thereof are rather complicated, thereby significantly increasing manufacturing costs of a glass panel and impeding large-scale production of relevant products.

### SUMMARY OF THE DISCLOSURE

In the prior art, a unique variety of masks is necessary for each type of low color shift design structure, such as an n+1 type low color shift design and an n+2 type low color shift design, for the performances of procedure steps including exposure, etching, etc. As can be seen, the manufacturing procedure thereof is rather tedious. Moreover, when one manufacturing type is switched to another, all masks should be replaced by new ones, which results in high costs and is against saving materials and steps. In addition, where different masks are inappropriately matched with each other, errors would easily occur.

For example, in a commonly used five mask procedure, if the manufacturing type is to be switched, e.g., from an n+1 type into an n+2 type, it will be necessary to entirely replace the design patterns of all the five masks, so as to alter the structure of a glass panel. This severely reduces production efficiency in conversion between different low color shift structure designs with plenty of adjustment to the procedure conditions and steps. Meanwhile, manufacturing costs of masks are significantly high.

To solve the above problems, the inventor of the present disclosure provides a modified glass panel.

The glass panel comprises a first metal layer used for forming scan lines and charge sharing lines, wherein one scan line and one relevant charge sharing line jointly correspond to a line of pixel units, and a wiring metal layer used for forming connecting wires, the connecting wires connecting the scan lines to the charge sharing lines, wherein the connecting wires each have a via hole portion, and connect to the scan line and/or the charge sharing line via a via hole in the via hole portion.

In this manner, a subsequently activated scan line can be used for activating a charge sharing line in a previous group, thus decreasing the amount of chips on film used in manufacturing and packaging procedures.

Preferably, the connecting wires each comprise a main wire portion extending along a straight line, and a first via hole portion, a second via hole portion, and a third via hole portion that are elongated and extend from the main wire portion perpendicularly thereto, wherein the second via hole portion is located between the first via hole portion and the third via hole portion.

With such structure design, a positional relationship between the scan line and the charge sharing line can be altered merely through altering patterning of a first mask, thus achieving conversion between the n+1 type low color shift structure to the n+2 type low color shift structure.

Preferably, an n+2 type low color shift structure is formed, which means that calculated from an end of the glass panel, an n^{th} charge sharing line is activated by an (n+2)^{th} scan line, n being a positive integer.

Preferably, in an n^{th} connecting wire, the first via hole portion and the third via hole portion respectively connect to the n^{th} charge sharing line and the (n+2)^{th} scan line through the via hole, while the second via hole portion suspends free.

Preferably, an n+1 type low color shift structure is formed, which means that calculated from an end of the glass panel, an n^{th} charge sharing line is activated by an (n+1)^{th} scan line, n being a positive integer.

Preferably, in the n^{th} connecting wire, the first via hole portion suspends free, while the second via hole portion and the third via hole portion respectively connect to the n^{th} charge sharing line and the (n+1)^{th} scan line through the via hole.

Through the n+1 or n+2 type low color shift design structure, while the color shift conditions of a display is effectively reduced, chips on film used in the manufacturing and packaging procedures can be saved. As a result, costs can be further decreased.

During manufacture of the glass panel according to the present disclosure, when an n+1 type low color shift structure and an n+2 type low color shift structure are used, one set of mask plates can be employed except that the mask patterning of the first metal layer M1 should be altered. This can significantly save material and procedure costs in manufacturing masks.

Preferably, the wiring metal layer and a second metal layer used for forming a source-drain of a thin film transistor are located at one and the same layer.

Preferably, the pixel unit comprises a main area provided with a pixel electrode and a sub area provided with a different pixel electrode, and the sub area is additionally provided with a sharing thin film transistor and a sharing capacitor, wherein the sharing thin film transistor has its source connected to the pixel electrode of the sub area, its drain connected to the sharing capacitor, and its gate connected to the charge sharing line.

Such being the case, when the n^{th} scan line is deactivated, and the n^{th} charge sharing line is activated by the (n+1)^{th} or the (n+2)^{th} scan line, the sharing thin film transistor is activated, such that the voltage of the liquid crystal capacitor and that of the storage capacitor will partly enter the sharing capacitor through the sharing thin film transistor. As a result, a potential difference occurs between the main area and the sub area. Moreover, the potential difference can be adjusted through an adjustment and control mechanism, thereby adjusting the color of a display picture and reducing color shift.

Preferably, the scan line controls the pixel electrodes in the main area and the sub area of the pixel unit simultaneously via a plurality of charging thin film transistors.

The present disclosure further provides a method for manufacturing the glass panel as described above. The glass panel is manufactured through a five mask procedure, comprising the steps of: forming a first metal layer on the glass panel through a first mask and covering the first metal layer with an insulation layer, forming an active layer on the insulation layer through a second mask, forming a second metal layer on the active layer through a third mask, forming a via hole layer on the second metal layer through a fourth mask, and forming an electrode layer on the via hole layer through a fifth mask, wherein a positional relationship between the scan line and the charge sharing line can be altered merely through altering patterning of the first mask, thus achieving conversion between the n+1 type low color shift structure and the n+2 type low color shift structure.

When the method of the present disclosure is used for manufacturing the glass panel of the present disclosure, one set of masks can be employed in both of the n+1 type low color shift structure and the n+2 type low color shift structure, except that the patterning of the mask for the first metal layer M1 should be altered. This can significantly save material and procedure costs in manufacturing masks. Meanwhile, through the n+1 or n+2 type low color shift design structure, while the color shift conditions of a display is effectively reduced, chips on film used in the manufacturing and packaging procedures can be saved. As a result, manufacturing costs can be further decreased.

The above technical features can be combined in any appropriate manner or be substituted by any equivalent technical features, so long as the purpose of the present disclosure can be achieved.

### BRIEF DESCRIPTION OF THE DRAWINGS

The present disclosure will be explained in more detail with reference to embodiments and accompanying drawings, in which:

FIG. 1 depicts procedure steps for manufacturing a glass panel in the prior art;

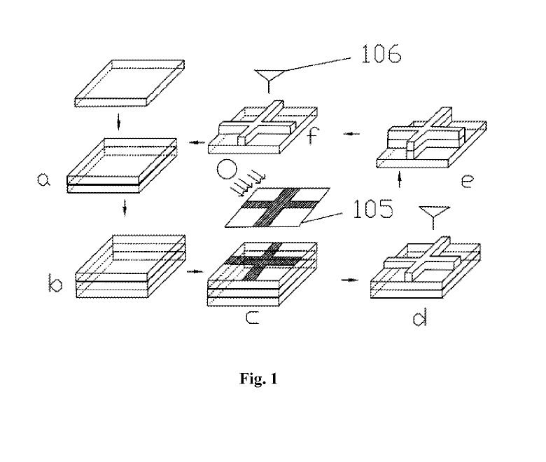

FIG. 2 shows a five mask procedure used for manufacturing a glass panel in the prior art;

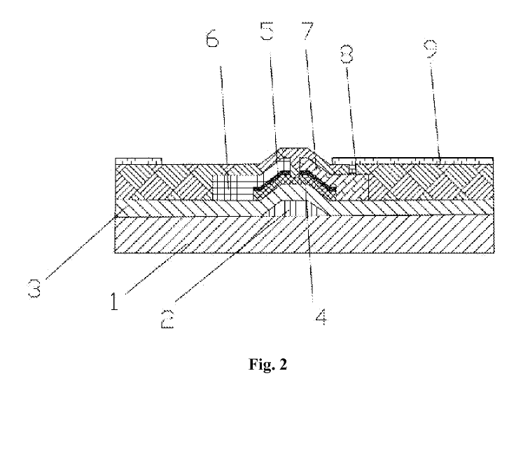

FIG. 3 schematically shows the structure of a pixel unit with a low color shift structure;

FIG. 4 shows a circuit diagram of a pixel unit with a low color shift structure;

FIG. 5 shows a signal diagram and a circuit diagram of an n+2 type low color shift structure;

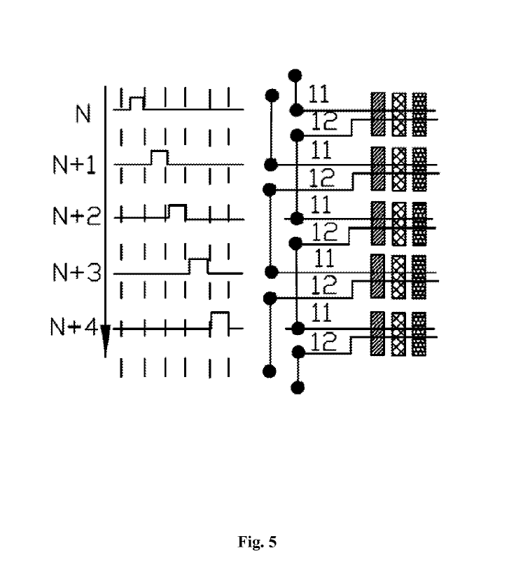

FIG. 6 schematically shows the structure of a glass panel with the n+2 type low color shift structure according to the present disclosure; and

FIG. 7 schematically shows the structure of a glass panel with an n+1 type low color shift structure according to the present disclosure.

In the drawings, the same components are indicated with the same reference signs. The figures are not drawn in accordance with an actual scale.

### DETAILED DESCRIPTION OF THE EMBODIMENTS

In the following, the present disclosure will be further explained in connection with the accompanying drawings.

The present disclosure provides a glass panel.

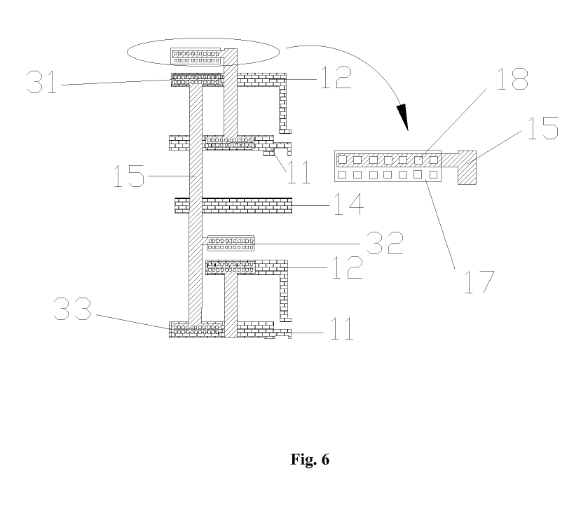

FIG. 6 schematically shows the structure of a glass panel with an n+2 type low color shift structure according to the present disclosure. As shown in FIG. 6, the glass panel according to the present disclosure comprises a first metal layer M1 used for forming scan lines 11 and charge sharing lines 12. One scan line 11 and one relevant charge sharing line 12 jointly correspond to a line of pixel units on the glass panel.

In a five mask procedure, the first metal layer M1 is formed through a first mask. That is, positions of the scan lines 11 and the charge sharing lines 12 are determined by a pattern of the first mask. The metal layer M1 can further comprise a common line 14 therein.

The glass panel according to the present disclosure further comprises a wiring metal layer used for forming connecting wires 15. The connecting wires 15 can connect the scan lines 11 to the charge sharing lines 12. Specifically, the connecting wires 15 each can have a via hole portion, and connect to the scan line 11 and/or the charge sharing line 12 through a via hole 18 in the via hole portion. FIG. 6 shows a detail view of the via hole portion at a right side thereof. The detail view illustrates that the via hole portion, through the via hole 18, connects the wiring metal layer and the first metal layer M1. Meanwhile, the two metal layers are covered with an ITO layer 17 thereon, which of course, may not be immediately adjacent to the metal layers.

FIG. 6 shows that the connecting wires 15 each comprise a main wire portion extending along a straight line. In the embodiment as shown in FIG. 6, the main wire portion extends along a longitudinal direction, i.e., the vertical direction in the figure. The connecting wires 15 each further comprise a first via hole portion 31, a second via hole portion 32, and a third via hole portion 33 that extend from the main wire portion perpendicularly thereto. As shown in FIG. 6, the first via hole portion 31, the second via hole portion 32, and the third via hole portion 33 are all elongated and extend horizontally, i.e., the lateral direction in the figure. FIG. 6 shows that the second via hole portion 32 is located between the first via hole portion 31 and the third via hole portion 33.

In the embodiment as shown in FIG. 6, the glass panel according to the present disclosure forms an n+2 type low color shift structure, which means that calculated from an end of the glass panel, an n^{th} charge sharing line 12 is activated by an (n+2)^{th} scan line 11, wherein n is a positive integer.

FIG. 6 shows that the first via hole portion 31 connects to the n^{th} charge sharing line 12 through the via hole 18, and the third via hole portion 33 connects to the (n+2)^{th} scan line 11 through the via hole 18, while the second via hole portion 32 suspends free, without connecting to any wire. In this manner, the following structure can be achieved. That is, the scan line 11 and the charge sharing line 12 connected to each other through the connecting wire 15 are spaced from each other by one scan line and one charge sharing line. It can thus be concluded that the n^{th} charging sharing line 12 is activated by the (n+2)^{th} scan line 11.

In one embodiment, when the five mask procedure is used for manufacturing a glass panel, the wiring metal layer can be configured in one and the same layer with a second metal layer M2 that is used for forming a source-drain of a thin film transistor. Thus, the number of masks required can be reduced and the manufacturing procedure can be shortened.

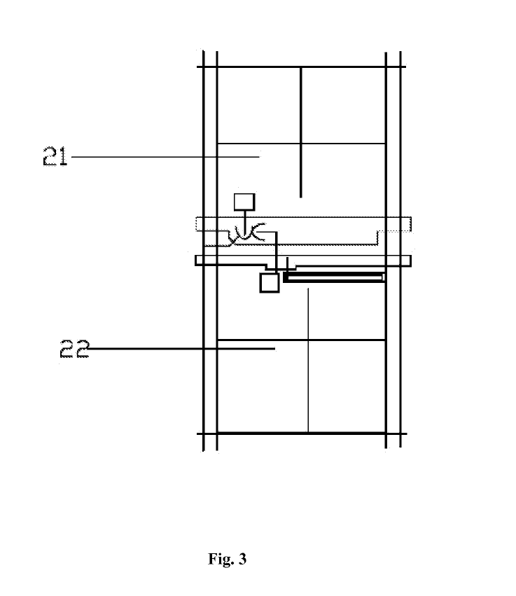

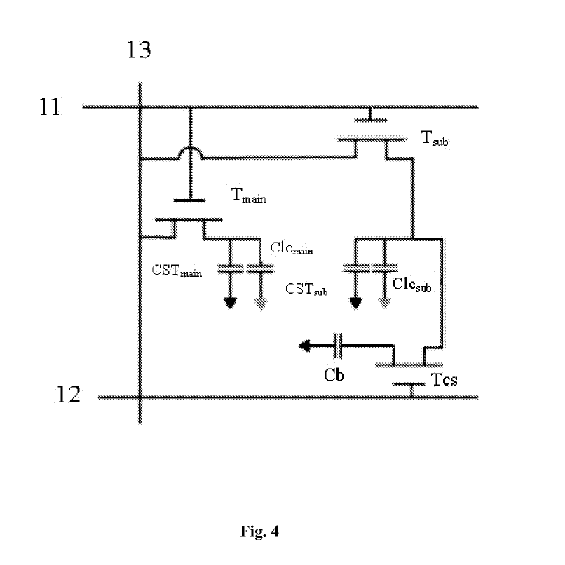

Reference can be made to FIG. 3 again. As previously explained, in a glass panel with the low color shift design, one pixel unit can comprise a main area 21 provided with a pixel electrode and a sub area 22 provided with a different pixel electrode. In connection with the circuit diagram as shown in FIG. 4, it is explicit that the sub area 22 is additionally provided with a sharing thin film transistor Tcs and a sharing capacitor Cb. The sharing thin film transistor Tcs has its drain connected to the sharing capacitor Cb, its gate connected to the charge sharing line 12, and its source connected to the pixel electrode of the sub area 22, which, as shown in FIG. 4, can for example, comprise a liquid crystal capacitor Clc_{sub} and a storage capacitor CST_{sub}.

The scan line 11 can control the pixel electrodes in the main area 21 and the sub area 22 of the pixel unit simultaneously via a plurality of charging thin film transistors Tₘₐᵢₙ and T_{sub}. FIG. 4 shows that the scan line 11 connects to a gate of the charging thin film transistor Tₘₐᵢₙ in the main area 21, and a gate of the charging thin film transistor T_{sub} in the sub area 22, respectively, so as to control activation and deactivation of the charging thin film transistor Tₘₐᵢₙ in the main area 21 and the charging thin film transistor T_{sub} in the sub area 22. When the scan line 11 is activated, the charging thin film transistor Tₘₐᵢₙ in the main area 21 and the charging thin film transistor T_{sub} in the sub area 22 are both activated, such that electric signals of the data line 13 can be transmitted to the liquid crystal capacitor Clcₘₐᵢₙ and the storage capacitor CSTₘₐᵢₙ that are located in the main area 21, and the liquid crystal capacitor Clc_{sub} and the storage capacitor CST_{sub} that are located in the sub area 22.

Meanwhile, the sharing thin film transistor Tsc has it source connected to the liquid crystal capacitor Clc_{sub} and the storage capacitor CST_{sub} that are located in the sub area 22, its drain connected to the sharing capacitor Cb, and its gate to connected to the charge sharing line 12. Thus, when the n^{th} scan line 11 is deactivated, and the n^{th} charge sharing line 12 is activated by the (n+2)^{th} scan line 11, the sharing thin film transistor Tcs is activated, such that the voltage of the liquid crystal capacitor Clc_{sub} and that of the storage capacitor CST_{sub} will partly enter the sharing capacitor Cb through the sharing thin film transistor Tcs. As a result, a potential difference occurs between the main area 21 and the sub area 22. Moreover, the potential difference can be adjusted through an adjustment and control mechanism, thereby adjusting the color of a displayed picture and reducing color shift.

However, in addition to the above n+2 type low color shift structure, the glass panel according to the present disclosure can also form an n+1 type low color shift structure, which means that calculated from an end of the glass panel, the n^{th} charge sharing line 12 is activated by the (n+1)^{th} scan line 11, wherein n is a positive integer.

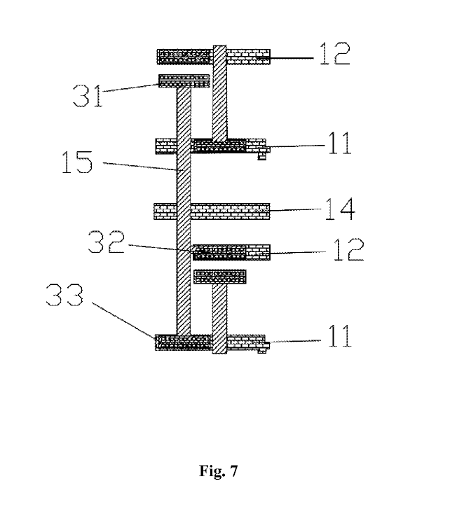

FIG. 7 shows, in the n+1 type low color shift structure, the first via hole portion 31 suspends free, while the second via hole portion 32 and the third via hole portion 33 respectively connect to the n^{th} charge sharing line 12 and the (n+1)^{th} scan line through the via hole. In this manner, the following structure can be achieved. That is, the scan line 11 and the charge sharing line 12 connected by a corresponding connecting wire 15 are adjacent to each other. It can thus be concluded that the n^{th} charging sharing line 12 is activated by the (n+1)^{th} scan line 11.

In one embodiment, when the five mask procedure is used for manufacturing a glass panel, the wiring metal layer can be configured in one and the same layer with a second metal layer M2 that is used for forming a source-drain of a thin film transistor. Thus, the number of masks required can be reduced and the manufacturing procedure can be shortened.

Reference can be made to FIG. 3 again. As previously explained, in a glass panel with the low color shift design, one pixel unit can comprise a main area 21 provided with a pixel electrode and a sub area 22 provided with a different pixel electrode. In connection with the circuit diagram as shown in FIG. 4, it is explicit that the sub area 22 is additionally provided with a sharing thin film transistor Tcs and a sharing capacitor Cb. The sharing thin film transistor Tcs has its drain connected to the sharing capacitor Cb, its gate connected to the charge sharing line 12, and its source connected to the pixel electrode of the sub area 22, which, as shown in FIG. 4, can for example, comprise a liquid crystal capacitor Clc_{sub} and a storage capacitor CST_{sub}.

The scan line 11 controls the pixel electrodes in the main area 21 and the sub area 22 of the pixel unit simultaneously via a plurality of charging thin film transistors Tₘₐᵢₙ and T_{sub}. FIG. 4 shows that the scan line 11 connects to a gate of the charging thin film transistor Tₘₐᵢₙ in the main area 21, and a gate of the charging thin film transistor T_{sub} in the sub area 22, respectively, so as to control activation and deactivation of the charging thin film transistor Tₘₐᵢₙ in the main area 21, and the charging thin film transistor T_{sub} in the sub area 22. When the scan line 11 is activated, the charging thin film transistor Tₘₐᵢₙ in the main area 21 and the charging thin film transistor T_{sub} in the sub area 22 are both activated, such that electric signals of the data line 13 can be transmitted to the liquid crystal capacitor Clcₘₐᵢₙ and the storage capacitor CSTₘₐᵢₙ that are located in the main area 21, and the liquid crystal capacitor Clc_{sub} and the storage capacitor CST_{sub} that are located in the sub area 22.

Meanwhile, the sharing thin film transistor Tsc has it source connected to the liquid crystal capacitor Clc_{sub} and the storage capacitor CST_{sub} that are located in the sub area 22, its drain connected to the sharing capacitor Cb, and its gate to connected to the charge sharing line 12. Thus, when the n^{th} scan line 11 is deactivated, and the n^{th} charge sharing line 12 is activated by the (n+1)^{th} scan line 11, the sharing thin film transistor Tcs is activated, such that the voltage of the liquid crystal capacitor Clc_{sub} and that of the storage capacitor CST_{sub} will partly enter the sharing capacitor Cb through the sharing thin film transistor Tcs. As a result, a potential difference occurs between the main area 21 and the sub area 22. Moreover, the potential difference can be adjusted through an adjustment and control mechanism, thereby adjusting the color of a displayed picture and reducing color shift.

The present disclosure further provides a method for manufacturing the glass panel as described above.

According to the method of the present disclosure, the glass panel can be manufactured through a five mask procedure, comprising the steps of:

forming a first metal layer on the glass panel through a first mask, and covering the first metal layer with an insulation layer;

forming an active layer on the insulation layer through a second mask;

forming a second metal layer on the active layer through a third mask;

forming a via hole layer on the second metal layer through a fourth mask; and

forming an electrode layer on the via hole layer through a fifth mask.

According to the method of the present disclosure, a positional relationship between the scan line and the charge sharing line can be altered merely through altering patterning of the first mask, thus achieving conversion between the n+1 type low color shift structure and the n+2 type low color shift structure.

When the method of the present disclosure is used for manufacturing the glass panel of the present disclosure, one set of masks can be employed in both of the n+1 type low color shift structure and the n+2 type low color shift structure, except that the patterning of the mask for the first metal layer M1 should be altered. This can significantly save material and procedure costs in manufacturing masks. Meanwhile, through the n+1 or n+2 type low color shift design structure, while the color shift conditions of a display is effectively reduced, chips on film used in the manufacturing and packaging procedures can be saved. As a result, manufacturing costs can be further decreased.

Although the present disclosure herein has been described with reference to particular embodiments, it is to be understood that these embodiments are merely illustrative of the principles and applications of the present disclosure. It is therefore to be understood that numerous modifications may be made to the illustrative embodiments and that other arrangements may be devised without departing from the spirit and scope of the present disclosure as defined by the appended claims. It will be appreciated that the various dependent claims and the features set forth therein can be combined in different ways than presented in the initial claims. It will also be appreciated that the features described in connection with individual embodiments may be shared with others of the described embodiments.

1. A glass panel, comprising:
a first metal layer used for forming scan lines and charge sharing lines, wherein one scan line and one relevant charge sharing line jointly correspond to a line of pixel units, and
a wiring metal layer used for forming connecting wires, the connecting wires connecting the scan lines to the charge sharing lines,
wherein the connecting wires each have a via hole portion, and connect to the scan line and/or the charge sharing line via a via hole in the via hole portion.

2. The glass panel according to claim 1, wherein the connecting wires each comprise a main wire portion extending along a straight line, and a first via hole portion, a second via hole portion, and a third via hole portion that are all elongated and extend from the main wire portion perpendicularly thereto, wherein the second via hole portion is located between the first via hole portion and the third via hole portion.

3. The glass panel according to claim 2, wherein an n+2 type low color shift structure is formed, which means that calculated from an end of the glass panel, an n^{th} charge sharing line is activated by an (n+2)^{th} scan line, n being a positive integer.

4. The glass panel according to claim 3, wherein in an n^{th} connecting wire, the first via hole portion and the third portion respectively connect to the n^{th} charge sharing line and the (n+2)^{th} scan line through the via hole, while the second via hole portion suspends free.

5. The glass panel according to claim 2, wherein an n+1 type low color shift structure is formed, which means that calculated from an end of the glass panel, an n^{th} charge sharing line is activated by an (n+1)^{th} scan line, n being a positive integer.

6. The glass panel according to claim 5, wherein in the n^{th} connecting wire, the first via hole portion suspends free, while the second via hole portion and the third via hole portion respectively connect to the n^{th} charge sharing line and the (n+1)^{th} scan line through the via hole.

7. The glass panel according to claim 1, wherein the wiring metal layer and a second metal layer used for forming a source-drain of a thin film transistor are located at one and the same layer.

8. The glass panel according to claim 1, wherein the pixel unit comprises a main area provided with a pixel electrode and a sub area provided with a different pixel electrode, and the sub area is additionally provided with a sharing thin film transistor and a sharing capacitor, wherein the sharing thin film transistor has its source connected to the pixel electrode of the sub area, its drain connected to the sharing capacitor, and its gate connected to the charge sharing line.

9. The glass panel according to claim 8, wherein the scan line controls the pixel electrodes in the main area and the sub area of the pixel unit simultaneously via a plurality of charging thin film transistors.

10. A method for manufacturing a glass panel, wherein the glass panel comprises:
a first metal layer used for forming scan lines and charge sharing lines, wherein one scan line and one relevant charge sharing line jointly correspond to a line of pixel units, and
a wiring metal layer used for forming connecting wires, the connecting wires connecting the scan lines to the charge sharing lines,
wherein the connecting wires each have a via hole portion, and connect to the scan line and/or the charge sharing line via a via hole in the via hole portion, and
wherein the glass panel is manufactured through a five mask procedure, comprising the steps of:
forming a first metal layer on the glass panel through a first mask and then covering the first metal layer with an insulation layer,
forming an active layer on the insulation layer through a second mask,
forming a second metal layer on the active layer through a third mask,
forming a via hole layer on the second metal layer through a fourth mask, and
forming an electrode layer on the via hole layer through a fifth mask,
wherein a positional relationship between the scan line and the charge sharing line can be altered merely through altering patterning of the first mask, thus achieving conversion between the n+1 type low color shift structure and the n+2 type low color shift structure.
